(19) United States
(12) Patent Application Publication
(10) Pub. No.: US 2025/0183103 A1
(43) Pub. Date: Jun. 5, 2025

(54) SEMICONDUCTOR PACKAGE

(71) Applicant: SAMSUNG ELECTRONICS CO., LTD., Suwon-si (KR)

(72) Inventor: Hyunjung Song, Suwon-si (KR)

(73) Assignee: SAMSUNG ELECTRONICS CO., LTD., Suwon-si (KR)

(21) Appl. No.: 18/826,981

(22) Filed: Sep. 6, 2024

(30) Foreign Application Priority Data
Nov. 30, 2023 (KR) 10-2023-0170748

(51) Int. Cl. H01L 23/29; H01L 23/00; H01L 23/31; H01L 23/538; H01L 25/065; H10B 80/00

(52) U.S. Cl. CPC H01L 23/295; H01L 23/3135; H01L 23/5385; H01L 24/29; H01L 24/32; H01L 24/73; H01L 25/0652; H01L 24/16; H01L 24/17; H01L 24/33; H01L 2224/16145; H01L 2224/16225; H01L 2224/17181; H01L 2224/29018; H01L 2224/29198; H01L 2224/32225; H01L 2224/33181; H01L 2224/73204; H01L 2225/06541; H10B 80/00

(57) ABSTRACT

A semiconductor package includes a base chip, at least one semiconductor chip disposed on the base chip, bump structures disposed between the base chip and the at least one semiconductor chip, an underfill layer surrounding the bump structures, the underfill layer having first pits in a surface thereof, and a first encapsulant in contact with a side surface of the at least one semiconductor chip and the surface of the underfill layer, on the base chip. At least some first pits, among the first pits, are connected to each other to form a first pit tunnel leading inwardly from the surface. At least a portion of the first encapsulant fills the first pit tunnel.

### CROSS-REFERENCE TO RELATED APPLICATION

This application is based on and claims priority to Korean Patent Application No. 10-2023-0170748, filed on Nov. 30, 2023 in the Korean Intellectual Property Office, the disclosure of which is incorporated herein by reference in its entirety.

### BACKGROUND

### 1. Field

The present disclosure relates to a semiconductor package.

### 2. Description of Related Art

Recently, high reliability has been required in semiconductor packages installed in electronic devices. In this case, delamination may occur at an interface between an underfill material fixing a semiconductor chip to a package substrate and an encapsulant. Accordingly, there is a need to develop technology to increase adhesion at an interface between different materials.

### SUMMARY

Provided is a semiconductor package having improved reliability.

According to an aspect of the disclosure, a semiconductor package includes: a package substrate including a first interconnection; an interposer on the package substrate, wherein the interposer includes a second interconnection connected to the first interconnection; a first chip structure and a second chip structure on the interposer, wherein the first chip structure and the second chip structure are connected to each other through the second interconnection, and wherein the second chip structure includes: a base chip; a chip stack on the base chip; and a first encapsulant surrounding a side surface of the chip stack, the first encapsulant including first pores in a surface thereof; a first underfill layer between the interposer and the first chip structure, between the interposer and the second chip structure, and in contact with at least a portion of a side surface of each of the first and second chip structures, wherein the first underfill layer includes a pit in a surface thereof; a second encapsulant covering at least a portion of the side surface of each of the first chip structure and the second chip structure and covering the surface of the first underfill layer, wherein the second encapsulant includes a second pore in a surface thereof; and a second underfill layer between the package substrate and the interposer, the second underfill layer in contact with at least a portion of a side surface of the second encapsulant, wherein at least a portion of the first underfill layer fills one or more of the first pores, wherein at least a portion of the second encapsulant fills one or more of the first pores and the pit, and wherein at least a portion of the second underfill layer fills the second pore.

According to an aspect of the disclosure, a semiconductor package includes: a base chip; a semiconductor chip on the base chip; a bump structure disposed between the base chip and the semiconductor chip; an underfill layer surrounding the bump structure, the underfill layer includes first pits in a surface thereof; and a first encapsulant in contact with a side surface of the semiconductor chip and the surface of the underfill layer, wherein at least some first pits, among the first pits, are connected to each other to form a first pit tunnel leading inwardly from the surface of the underfill layer, and wherein at least a portion of the first encapsulant fills the first pit tunnel.

According to an aspect of the disclosure, a semiconductor package includes: a base substrate; a first semiconductor chip on the base substrate; a connection bump between the base substrate and the first semiconductor chip; a second semiconductor chip on the first semiconductor chip; a first encapsulant in contact with a side surface of the second semiconductor chip, wherein the first encapsulant includes first pores in a surface thereof; a first underfill layer surrounding the connection bump, wherein the first underfill layer is in contact with a side surface of a lower region of the first encapsulant, and wherein the first underfill layer includes a first pit in a surface thereof; and a second encapsulant, wherein the second encapsulant is in contact with a side surface of an upper region of the first encapsulant, wherein the first underfill layer fills a first pore, among the first pores, positioned in the lower region of the first encapsulant, and wherein the second encapsulant fills the first pit and a first pore, among the first pores, positioned in the upper region of the first encapsulant.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor package according to an example embodiment;

FIG. 2 is a schematic cross-sectional view of a semiconductor package according to an example embodiment;

FIGS. 3A and 3B are schematic partially enlarged views of a semiconductor package according to an example embodiment;

FIGS. 4A and 4B are schematic partially enlarged views of a semiconductor package according to an example embodiment;

FIGS. 5A and 5B are schematic partially enlarged views of a semiconductor package according to an example embodiment;

FIG. 6 is a schematic cross-sectional view of a semiconductor package according to an example embodiment;

FIG. 7 is a schematic cross-sectional view of a semiconductor package according to an example embodiment;

FIG. 8 is a schematic cross-sectional view of a semiconductor package according to an example embodiment;

FIG. 9 is a schematic cross-sectional view of a semiconductor package according to an example embodiment; and

FIGS. 10, 11, 12, 13, 14, 15, 16, 17, 18, 19, 20, 21, 22, 23, 24 and 25 are schematic cross-sectional views and partially enlarged views illustrating a method of manufacturing a semiconductor package according to an embodiment of the present disclosure.

### DETAILED DESCRIPTION

Hereinafter, example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

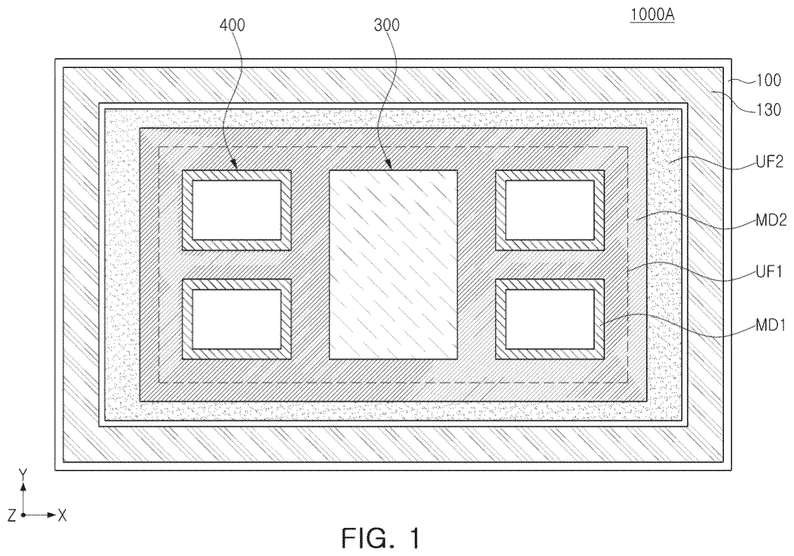

FIG. 1 is a schematic plan view of a semiconductor package 1000A according to an example embodiment.

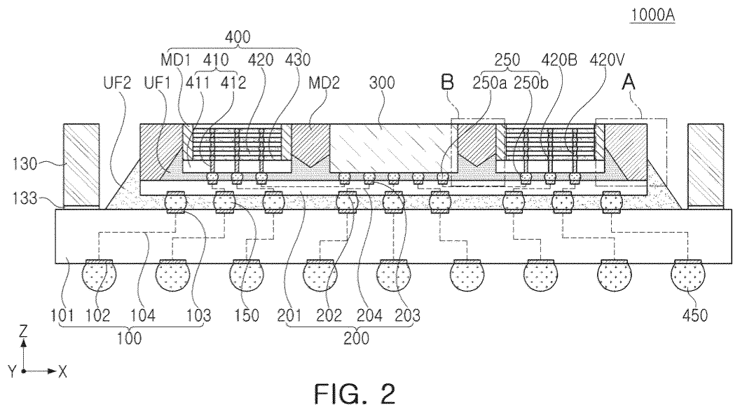

FIG. 2 is a schematic cross-sectional view of a semiconductor package 1000A according to an example embodiment.

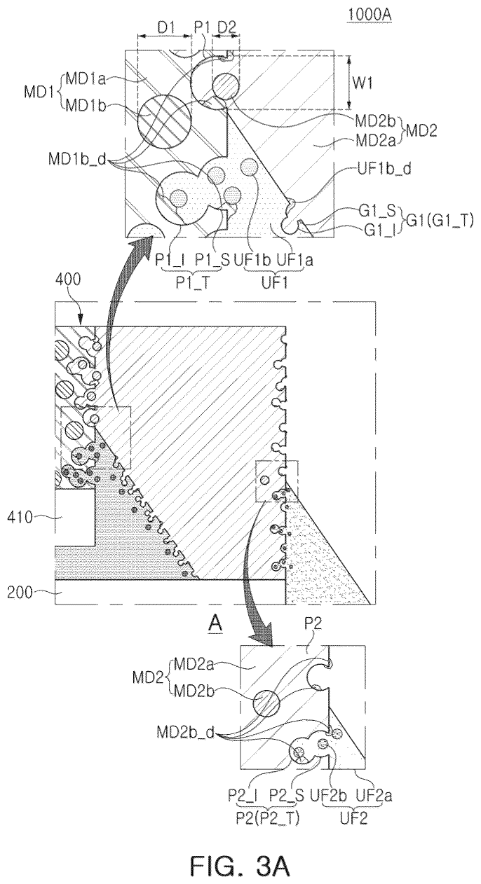

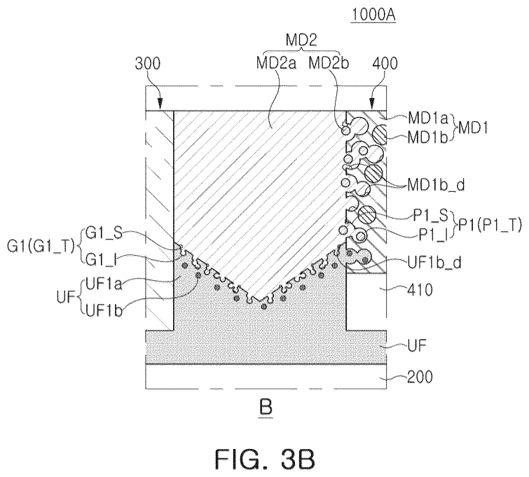

FIG. 3A is a schematic partially enlarged view of region “A” of the semiconductor package 1000A according to example embodiments. FIG. 3B is a schematic partially enlarged view of region “B” of the semiconductor package 1000A according to example embodiments.

Referring to FIGS. 1 to 3B, the semiconductor package 1000A according to an example embodiment may include a package substrate 100, an interposer 200, and a plurality of semiconductor chips 300 and 400 (or “chip structures”).

According to an example embodiment, the semiconductor package 1000A may include a base chip 410, a plurality of semiconductor chips 420 vertically stacked on the base chip 410, and a first encapsulant MD1, covering the plurality of semiconductor chips 420, on the base chip 410. The base chip 410 may include a base substrate 411 and a plurality of through-electrodes 412 penetrating the base substrate 411.

In addition, according to an example embodiment, the semiconductor package 1000A may include a first underfill layer UF1, fixing the plurality of semiconductor chips 300 and 400, on the interposer 200, and a second encapsulant MD2 covering a surface of the first underfill layer UF1 and side surfaces of the plurality of semiconductor chips 300 and 400, and may further include a second underfill layer UF2, fixing the interposer 200, on the package substrate 100.

According to the present disclosure, surfaces of the first encapsulant MD1, the first underfill layer UF1, the second encapsulant MD2, and the second underfill layer UF2 may be respectively surface-treated using a method such as wet etching, thereby increasing an adhesion area between the first encapsulant MD1, the first underfill layer UF1, the second encapsulant MD2, and the second underfill layer UF2. Accordingly, the semiconductor package 1000A may have improved reliability.

Specifically, the surface of the first encapsulant MD1 may be surface-treated to form pores therein, and then the first underfill layer UF1 may be disposed on the treated surface, thereby increasing an adhesion area between the first encapsulant MD1 and the first underfill layer UF1. Similarly, the surface of the first underfill layer UF1 may be surface-treated to form pits therein, and then the second encapsulant MD2 may be disposed on the treated surface, thereby increasing an adhesion area between the first underfill layer UF1 and the second encapsulant MD2. Accordingly, the first underfill layer UF1 and the second encapsulant MD2 protecting the plurality of semiconductor chips 300 and 400 may be prevented from cracking or breaking due to externally applied mechanical stress.

Similarly, according to an example embodiment, the surface of the second encapsulant MD2 may be surface-treated to form pores therein, and then the second underfill layer UF2 may be disposed on the treated surface, thereby increasing an adhesion area between the second encapsulant MD2 and the second underfill layers UF2. Accordingly, mechanical stress applied to the package substrate 100 may be reduced or prevented from being transferred to the interposer 200, thereby causing the semiconductor package 1000A to have improved reliability.

The package substrate 100 may include an insulating layer 101, lower pads 102 disposed on a lower portion thereof, upper pads 103 disposed on an upper portion thereof, and an interconnection 104 (or “first interconnection”) electrically connecting the lower pads 102 and the upper pads 103 to each other. The package substrate 100 may be a support substrate on which the interposer 200 is mounted, where the plurality of semiconductor chips 300 and 400 are in turn mounted on the interposer 200. The package substrate 100 may be a substrate for a semiconductor package including a printed circuit board (PCB), a ceramic substrate, a glass substrate, a tape interconnection substrate, or the like. In some example embodiments, the package substrate 100 may further include a solder resist layer covering the lower pads 102 and the upper pads 103.

The insulating layer 101 may include an insulating resin electrically and physically protecting the interconnection 104, for example, a thermosetting resin such as an epoxy resin, a thermoplastic resin such as polyimide, or a prepreg, Ajinomoto build-up film (ABF), or frame retardant 4 (FR4) including an inorganic filler and/or a glass fiber (or glass cloth or glass fabric).

The interconnection 104 may extend from the inside of the insulating layer 101 to electrically connect the lower pad 102 and the upper pad 103 to each other. The interconnection 104 may include a conductive pattern and a conductive via forming an electrical connection path. The interconnection 104 may include at least one metal or an alloy of two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe).

External connection terminals 450 may be disposed on a lower surface of the package substrate 100. The external connection terminals 450 may electrically connect the semiconductor package 1000A to an external device such as a module substrate, a main board, or the like. The external connection terminals 450 may include a solder ball and/or a conductive filler. The external connection terminals 450 may have, for example, a flip-chip connection structure having a grid array such as a pin grid array, ball grid array, or a land grid array. The external connection terminals 450 may be electrically connected to the lower pads 102 of the package substrate 100.

The interposer 200 may be disposed on the package substrate 100. The interposer 200 may be a PCB, a ceramic substrate, a tape substrate, or the like for interconnecting the plurality of semiconductor chips 300 and 400 disposed on the interposer 200 and the package substrate 100. The interposer 200 may include a dielectric layer 201 and an interconnection 204 (or “second interconnection”). The dielectric layer 201 may include an insulating resin, for example, a thermosetting resin such as an epoxy resin, a thermoplastic resin such as polyimide, or a prepreg, ABF, or FR4 including an inorganic filler and/or a glass fiber (or glass cloth or glass fabric). The interconnection 204 may extend from the inside of the dielectric layer 201 to electrically connect a lower pad 202 and an upper pad 203 to each other. The interconnection 204 may include a conductive pattern and a conductive via forming an electrical connection path. The interconnection 204 may include at least one metal or an alloy of two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe). The interconnection 204 of the interposer 200 may be connected to the interconnection 104 of the package substrate 100 through connection bumps 150.

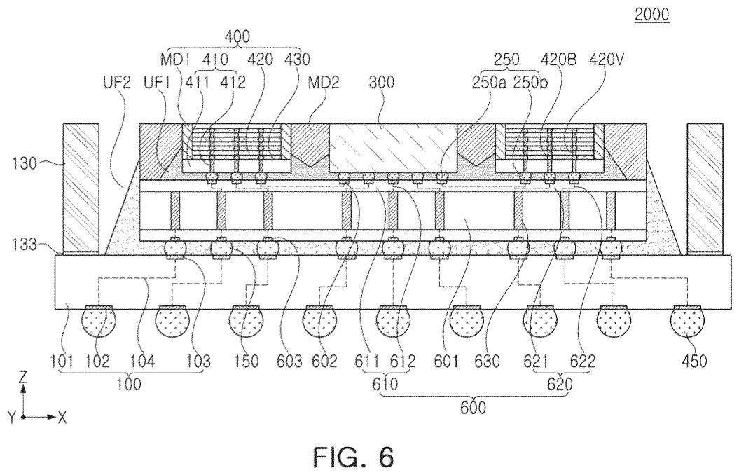

In one or more example embodiments, the interposer 200 may be a silicon interposer substrate including a through-silicon via (TSV). In this case, the dielectric layer 201 may include silicon oxide, silicon nitride, or the like, which will be described in detail below with reference to FIG. 6.

The plurality of semiconductor chips 300 and 400 may be disposed on the interposer 200. The plurality of semiconductor chips 300 and 400 may include a first semiconductor chip 300 (or “first chip structure”) and a second semiconductor chip 400 (or “second chip structure”), spaced apart from each other in a horizontal direction (X-direction), on the interposer 200. The first semiconductor chip 300 and the second semiconductor chip 400 may include different types of semiconductor chips. For example, the first semiconductor chip 300 may include a logic chip such as a central processor (CPU), a graphics processor (GPU), a field-programmable gate array (FPGA), a digital signal processor, an encryption processor, a microprocessor, a microcontroller, an analog-digital converter, or an application-specific IC (ASIC). The second semiconductor chip 400 may include a memory chip such as dynamic RAM (DRAM), static RAM (SRAM), phase change RAM (PRAM), resistive RAM (ReRAM), ferroelectric random access memory (FeRAM), magnetic RAM (MRAM), or flash memory. According to the present example embodiment, the second semiconductor chip 400 may be provided as a high-performance memory device such as high bandwidth memory (HBM), hybrid memory cube (HMC), or the like. In this case, the second semiconductor chip 400 may be referred to as a second chip structure.

The second chip structure may include a plurality of second semiconductor chips 420 (or “chip stack”) vertically stacked on the base chip 410. The plurality of second semiconductor chips 420 may be electrically connected to each other through vias 420V passing through at least some second semiconductor chips 420, among the second semiconductor chips 420. A fillet layer 430, surrounding the connection bumps 420B, may be disposed between the plurality of second semiconductor chips 420. The fillet layer 430 may be an underfill layer including an insulating material such as an epoxy resin. For example, the fillet layer 430 may include a non-conductive film (NCF). The plurality of second semiconductor chips 420 may include a memory chip such as DRAM, SRAM, PRAM, ReRAM, FeRAM, MRAM, or flash memory. The chip structure may be, for example, a high-performance memory device such as HBM, HMC, or the like.

The chip structure may further include a first encapsulant MD1, encapsulating the plurality of second semiconductor chips 420, on the base chip 410. The first encapsulant MD1 may surround side surfaces of the plurality of second semiconductor chips 420. The first encapsulant MD1 may be in direct contact with a surface of the fillet layer 430. The first encapsulant MD1 may be formed of an insulating material such as, for example, an epoxy mold compound (EMC), but the material of the first encapsulant MD1 is not limited thereto.

Referring to FIGS. 3A and 3B together, the first encapsulant MD1 may include a first insulating resin MD1a and first fillers MD1b. The first insulating resin MD1a may include, for example, a thermosetting resin such as an epoxy resin. The first fillers MD1b may be inorganic fillers dispersed in the first insulating resin MD1a. The first fillers MD1b may be crystalline silica particles having a diameter (or “first diameter D1”) ranging from about 1 μm to about 60 μm. The first fillers MD1b may include spherical crystalline silica particles, but the present disclosure is not limited thereto. The first fillers MD1b may be, for example, oval crystalline silica particles.

The first encapsulant MD1 may have first pores P1. The first pores P1 may include first surface pores P1_S positioned in the surface of the first encapsulant MD1, and first internal pores P1_I connected to the first surface pores P1_S, the first internal pores P1_I positioned in the first encapsulant MD1. At least some first pores, among the first pores P1, may be connected to each other to form a first pore tunnel P1_T extending from the surface to the inside of the first encapsulant MD1. For example, the first surface pores P1_S and the first internal pores P1_I may be connected to each other to form the first pore tunnel P1_T. A width W1 of each of regions of the first surface pores P1_S, opened in the surface of the first encapsulant MD1, may be substantially the same as or smaller than a diameter D1 of each of the first fillers MD1b.

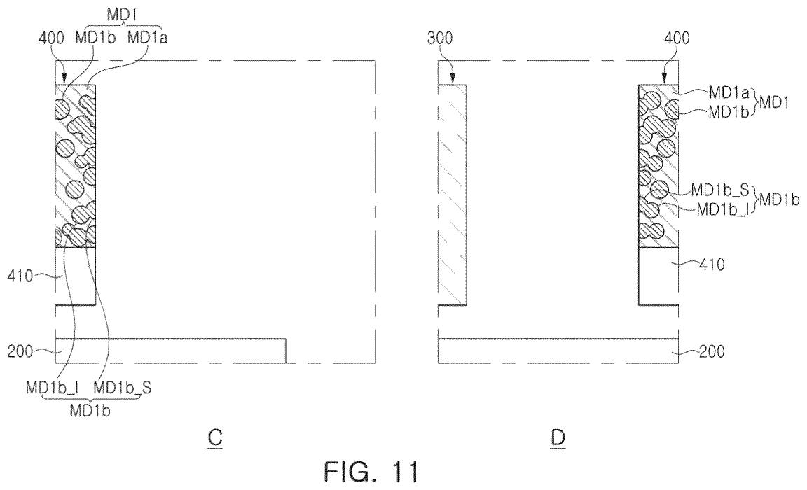

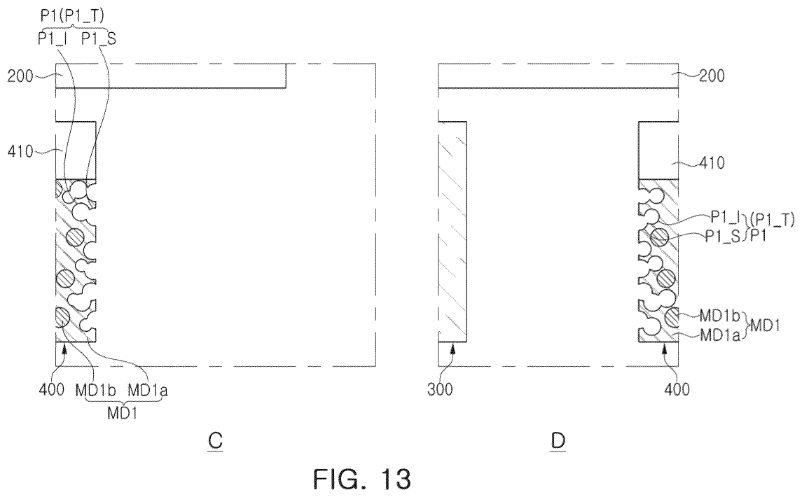

Referring to FIGS. 11 and 13 together with FIGS. 3A and 3B, the first pores P1 may be pores formed when the first fillers MD1b are removed from the surface of the first encapsulant MD1. Accordingly, a volume of each of the first pores P1 may be substantially the same as a volume of each of the first fillers MD1b. Fragments MD1b_d of the first filler MD1b that have not yet been removed and remain may be present in the first pores P1. At least some fragments, among the fragments MD1b_d of the first filler MD1b, may deviate from the first pores P1 to be present on the surface of the first encapsulant MD1. In this case, the at least some fragments, among the fragments MD1b_d of the first filler, may be disposed on the surface of the first encapsulant MD1 to be oriented in a vertical direction (Z-direction).

The plurality of semiconductor chips 300 and 400 may be attached to the interposer 200 by bump structures 250. The bump structures 250 may include a first bump structure 250a and a second bump structure 250b, on the interposer 200 of the first semiconductor chip 300 and the second semiconductor chip 400. The first bump structure 250a may electrically connect a connection pad of the first semiconductor chip 300 and the upper pad 203 of the interposer 200 to each other, and the second bump structure 250b may electrically connect a connection pad of the second semiconductor chip 400 and the upper pad 203 of the interposer 200 to each other. The bump structures 250 may include tin (Sn), indium (In), bismuth (Bi), antimony (Sb), copper (Cu), silver (Ag), zinc (Zn), lead (Pb), and/or alloys thereof (for example, Sn—Ag—Cu).

The first underfill layer UF1, surrounding the bump structures 250, may be disposed between the interposer 200 and the plurality of semiconductor chips 300 and 400. The first underfill layer UF1 may be disposed to be in contact with a side surface of the first semiconductor chip 300 and at least a portion of the first encapsulant MD1 of the second semiconductor chip 400. For example, the first underfill layer UF1 may be formed to extend in the vertical direction (Z-direction) to be in contact with a surface of a lower region of the first encapsulant MD1.

The first underfill layer UF1 may include an insulating resin UF1a and first binders UF1b. The insulating resin UF1a may include, for example, a thermosetting resin such as an epoxy resin. The first binders UF1b may be inorganic fillers dispersed in the insulating resin UF1a. The first binders UF1b may be crystalline silica particles having a diameter ranging from about 1 μm to about 5 μm. The first binders UF1b may include spherical crystalline silica particles, but the present disclosure is not limited thereto. The first binders UF1b may be, for example, oval crystalline silica particles.

The first underfill layer UF1 may fill at least first pores, among the first pores P1. For example, the insulating resin UF1a of the first underfill layer UF1 may be introduced into the first pores P1 positioned in the lower region of the first encapsulant MD1. The first binders UF1b may also be introduced into the first pores P1. In this case, at least first binders, among the first binders UF1b, may be in contact with the fragments MD1b_d of the first filler in the first pores P1 or on the surface of the first encapsulant MD1.

The first underfill layer UF1 may have first pits G1. The first pits G1 may include first surface pits G1_S, positioned in a surface of the first underfill layer UF1, and first internal pits G1_I connected to the first surface pits G1_S and positioned in the first underfill layer UF1. At least some first pits G1, among the first pits G1, may be connected to each other to form a first pit tunnel G1_T extending from the surface to the inside of the first underfill layer UF1. For example, the first surface pits G1_S and the first internal pits G1_I may be connected to each other to form the first pit tunnel G1_T. A width of each of regions of the first surface pits G1_S, opened by the surface of the first underfill layer UF1, may be substantially the same as, or smaller than, a diameter of each of the first binders UF1b.

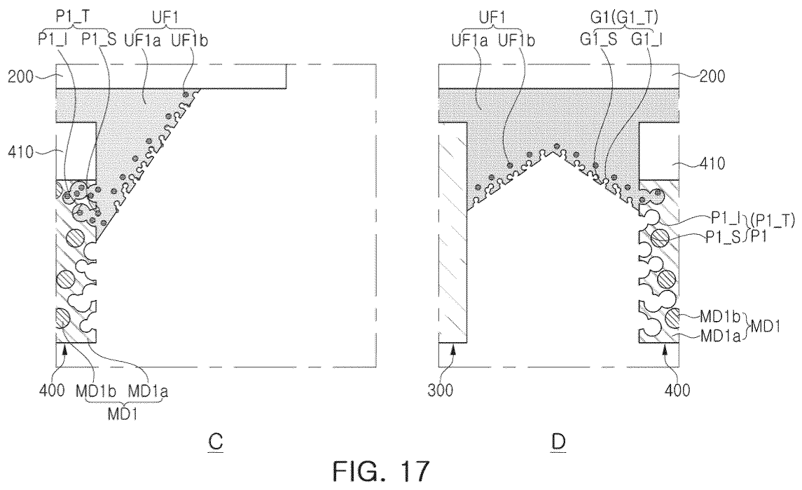

Referring to FIG. 17 together with FIGS. 3A and 3B, the first pits G1 may be pits formed when the first binders UF1b are removed from the surface of the first underfill layer UF1. Accordingly, a volume of each of the first pits G1 may be substantially the same as a volume of each of the first binders UF1b. Fragments UF1b_d of the first binders UF1b that have not yet been removed and remain may be present in the first pits G1. At least some fragments, among the fragments UF1b_d of the first binder UF1b, may deviate from the first pits G1 to be present on the surface of the first underfill layer UF1.

The second encapsulant MD2, encapsulating the first underfill layer UF1 and the plurality of semiconductor chips 300 and 400, may be disposed on the interposer 200. The second encapsulant MD2 may be in direct contact with the surface of the first underfill layer UF1. The second encapsulant MD2 may be in contact with a side surface of the first semiconductor chip 300 and at least a portion of the first encapsulant MD1 of the second semiconductor chip 400. For example, the second encapsulant MD2 may be disposed to be in contact with a surface of an upper region of the first encapsulant MD1.

The second encapsulant MD2 may include a second insulating resin MD2a and second fillers MD2b. The second insulating resin MD2a may have features the same as or similar to those of the first insulating resin MD1a. The second fillers MD2b may have features the same as or similar to those of the first fillers MD1b, except that the second fillers MD2b may have a diameter different from the first diameter D1 of the first fillers MD1b. The second fillers MD2b may have a diameter (or “second diameter D2”), smaller than the first diameter D1 of the first fillers MD1b. For example, the second fillers MD2b may have a diameter ranging from about 1 μm to about 40 μm.

The second encapsulant MD2 may fill one or more first pores, among the first pores P1. For example, the second insulating resin MD2a of the second encapsulant MD2 may be introduced into the first pores P1 positioned in the upper region of the first encapsulant MD1. The second fillers MD2b may also be introduced into the first pores P1. In this case, at least second fillers, among the second fillers MD2b, may be in contact with a fragment MD1b_d of the first filler in the first pores P1 or on the surface of the first encapsulant MD1.

Similarly, the second encapsulant MD2 may fill one or more first pits, among the first pits G1. For example, the second insulating resin MD2a of the second encapsulant MD2 may be introduced into the first pits G1. In this case, at least a portion of the second insulating resin MD2a may be in contact with the fragments UF1b_d of the first binder in the first pits G1 or on the surface of the first underfill layer UF1.

According to the present disclosure, the first underfill layer UF1 may be disposed on the first encapsulant MD1 having predetermined pores in a surface thereof, and at least a portion of the first underfill layer UF1 may be introduced into the predetermined pores, thereby increasing an adhesion area between the first encapsulant MD1 and the first underfill layer UF1. Similarly, the second encapsulant MD2 may be disposed on the first encapsulant MD1 and the first underfill layer UF1 having predetermined pits on a surface thereof, and at least a portion of the second encapsulant MD2 may be introduced into the predetermined pores and pits, thereby increasing an adhesion area between the first encapsulant MD1, the first underfill layer UF1, and the second encapsulant MD2. Accordingly, the plurality of semiconductor chips 300 and 400 may be effectively protected from externally applied mechanical stress, thereby providing the semiconductor package 1000A with improved reliability.

A volume of the insulating resin UF1a of the first underfill layer UF1, filling the first pores P1 positioned in the lower region of the first encapsulant MD1, may be smaller than a volume of the second insulating resin MD2a of the second encapsulant MD2, filling the first pores P1 positioned in the upper region of the first encapsulant MD1. This may be understood because a significant portion of the first underfill layer UF1 is formed to surround the bump structures 250 below the second semiconductor chip 400.

The number of first binders UF1b, introduced into the first pores P1 positioned in the lower region of the first encapsulant MD1, may be greater than the number of second fillers MD1b, introduced into the first pores P1 positioned in the upper region of the first encapsulant MD1. This may be understood because the first binders UF1b have a diameter smaller than the diameter of the second fillers MD1b.

The second encapsulant MD2 may have second pores P2 on one side surface thereof. The second pores P2 of the second encapsulant MD2 may have features the same as or similar to those of the first pores P1 of the first encapsulant MD1. For example, the second pores P2 may include second surface pores P2_S positioned in the surface of the second encapsulant MD2, and second internal pores P2_I connected to the second surface pores P2_S and positioned in the second encapsulant MD2. At least second pores, among the second pores P2, may be connected to each other to form a second pore tunnel P2_T extending long from the surface to the inside of the second encapsulant MD2. For example, the second surface pores P2_S and the second internal pores P2_I may be connected to each other to form the second pore tunnel P2_T. A width W2 of each of regions of the second surface pores P2_S, opened by the surface of the second encapsulant MD2, may be substantially the same as to or smaller than the diameter D2 of the second fillers MD2b.

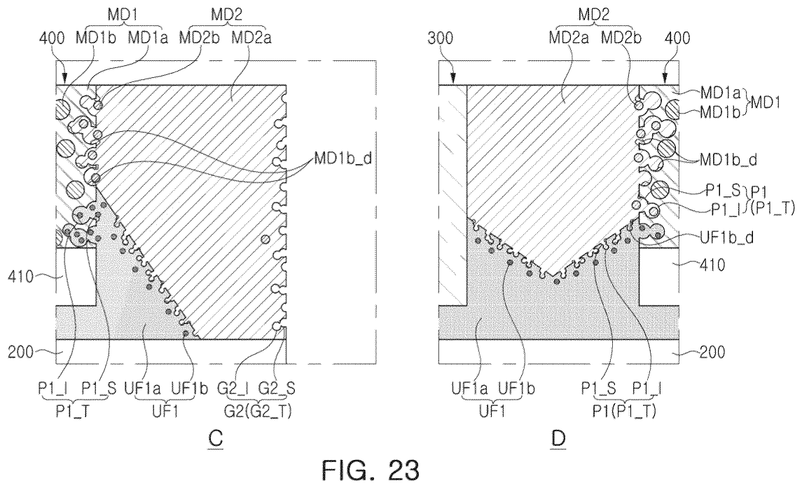

Referring to FIG. 23, the second pores P2 may be pores formed when the second fillers MD2b are removed from the surface of the second encapsulant MD2. Accordingly, a volume of each of the second pores P2 may be substantially the same as a volume of each of the second fillers MD2b. Fragments MD2b_d of the second filler MD2b that have not yet been removed and remain may be present in the second pores P2. At least some fragments, among the fragments MD2b_d of the second filler MD2b, may deviate from the second pores P2 to be present on the surface of the second encapsulant MD2.

The second underfill layer UF2, surrounding the connection bumps 150, may be disposed between the package substrate 100 and the interposer 200. The second underfill layer UF2 may be disposed to be in contact with a side surface of the interposer 200 and at least a portion of the second encapsulant MD2. For example, the second underfill layer UF2 may be formed to extend in the vertical direction (Z-direction) to be in contact with a surface of a lower region of the second encapsulant MD2.

The second underfill layer UF2 may include an insulating resin UF2a and second binders UF2b. The insulating resin UF2a of the second underfill layer UF2 may have features the same as or similar to those of the insulating resin UF1a of the first underfill layer UF1. Similarly, the second binders UF2b may have features the same as or similar to those of the first binders UF1b.

The second underfill layer UF2 may fill at least second pores, among the second pores P2. For example, the insulating resin UF2a of the second underfill layer UF2 may be introduced into the second pores P2 positioned in the lower region of the second encapsulant MD2. The second binders UF2b may also be introduced into the second pores P2. In this case, at least second binders, among the second binders UF2b, may be in contact with the fragments MD2b_d of the second filler in the second pores P2 or on the surface of the second encapsulant MD2.

According to the present disclosure, the second underfill layer UF2 may be disposed between the interposer 200 and the package substrate 100. In this case, the second underfill layer UF2 may be disposed to extend in the vertical direction, such that the second underfill layer UF2 may be in contact with at least a portion of the second encapsulant MD2 having predetermined pores on a surface thereof, thereby increasing an adhesion area between the second encapsulant MD2 and the second underfill layer UF2. Accordingly, mechanical stress applied to the package substrate 100 may be reduced or prevented from being transferred to the interposer 200, thereby providing the semiconductor package 1000A with improved reliability.

The second underfill layer UF2 may not fill the second pores P2 positioned in an upper region of the second encapsulant MD2. In other words, the second pores P2, positioned in the upper region of the second encapsulant MD2, may be exposed in a state of being hollow. For example, the second pores P2, positioned in the upper region of the second encapsulant MD2, may oppose a side surface of a stiffener 130 in the horizontal direction (X-direction).

The stiffener 130 may be disposed on the package substrate 100. The stiffener 130 may be attached to the package substrate 100 by an adhesive layer 133. The stiffener 130 may extend along a circumference of the package substrate 100. The stiffener 130 may be configured to control warpage of the semiconductor package 1000A.

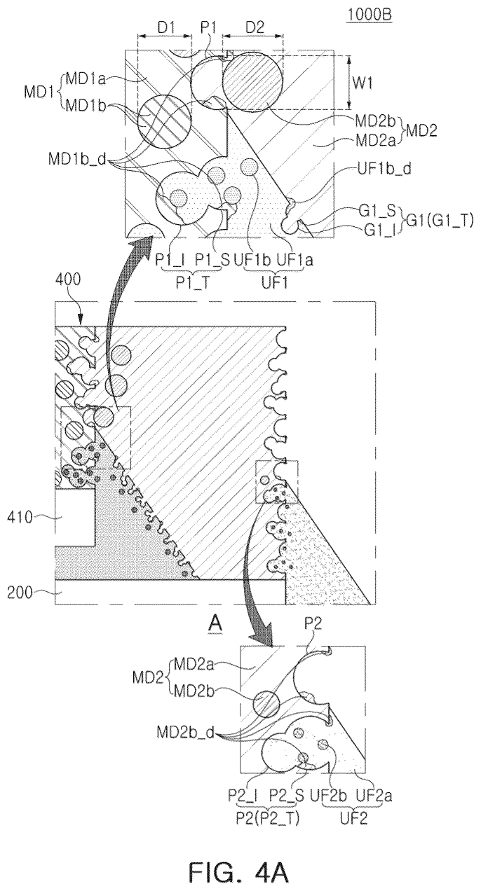

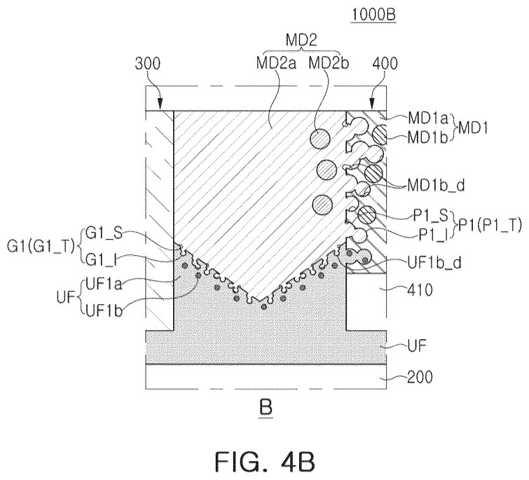

FIG. 4A is a schematic partially enlarged view of region “A” of the semiconductor package 1000B according to an example embodiment. FIG. 4B is a schematic partially enlarged view of region “B” of the semiconductor package 1000B according to an example embodiment.

Referring to FIGS. 4A and 4B, the semiconductor package 1000B may have features the same as or similar to those described with reference to FIGS. 1 to 3B, except that a second filler MD2b of a second encapsulant MD2 is not disposed in a first pore P1 of a first encapsulant MD1.

Referring to FIGS. 4A and 4B, the second filler MD2b of the second encapsulant MD2 may have a size substantially the same as or larger than a size of a first filler MD1b of the first encapsulant MD1. For example, a second diameter D2 of the second filler MD2b may be substantially the same as or larger than a first diameter D1 of the first filler MD1b. Accordingly, a width W1 of each of regions of first surface pores P1_S, opened by a surface of the first encapsulant MD1, may be smaller than the second diameter D2 of each of the second fillers MD2b. Accordingly, the second filler MD2b may not be disposed in the first pore P1, but may be disposed only on the outside of the first pore P1. On the outside of the first pore P1, the second filler MD2b may be in contact with fragments MD1b_d of the first filler present on the surface of the first encapsulant MD1.

When compared to FIGS. 3A and 3B, the number of second binders UF2b of a second underfill layer UF2, present in a second pore P2, may be further increased with an increase in size of the second pore P2.

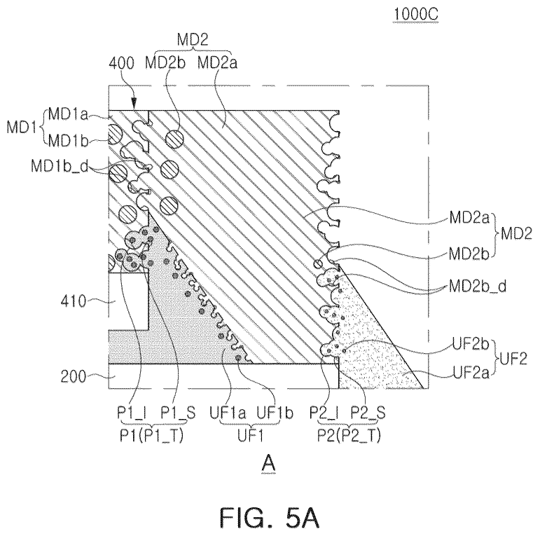

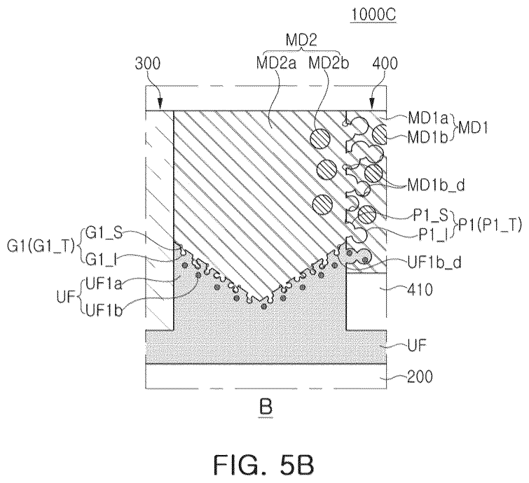

FIG. 5A is a schematic partially enlarged view of region “A” of the semiconductor package 1000C according to an example embodiment. FIG. 5B is a schematic partially enlarged view of region “B” of the semiconductor package 1000C according to an example embodiment.

Referring to FIGS. 5A and 5B, the semiconductor package 1000C may have features the same as or similar to those described with reference to FIGS. 1 to 4B, except that a first insulating resin MD1a of a first encapsulant MD1 and a second insulating resin MD2a of a second encapsulant MD2 are the same insulating resin.

According to the present disclosure, the second encapsulant MD2 may be disposed on the first encapsulant MD1 having predetermined pores in a surface thereof and a first underfill layer UF1 having predetermined pits in a surface thereof, and the second encapsulant MD2 may be introduced into the pores and pits, thereby increasing an adhesion area between the first encapsulant MD1, the first underfill layer UF1, and the second encapsulant MD2. Accordingly, even when the first insulating resin MD1a of the first encapsulant MD1 and the second insulating resin MD2a of the second encapsulant MD2 include the same insulating resin, the semiconductor package 1000C having improved reliability may be provided. A first filler MD1b of the first encapsulant MD1 and a second filler MD2b of the second encapsulant MD2 may have substantially the same size, but the present disclosure is not limited thereto. For example, a second diameter D2 of the second filler MD2b may be smaller than a first diameter D1 of the first filler MD1b, and accordingly, the second filler MD2b may be disposed in a first pore P1.

FIG. 6 is a schematic cross-sectional view of a semiconductor package 2000 according to an example embodiment.

Referring to FIG. 6, the semiconductor package 2000, according to an example embodiment, may be the same as or similar to that described with reference to FIGS. 1 to 5B, except that an interposer is a silicon interposer substrate 600 including a through-silicon via.

Referring to FIG. 6, the interposer substrate 600 may include a semiconductor substrate 601, an upper circuit layer 610, a lower circuit layer 620, and through-vias 630. The interposer substrate 600 may include a lower pad 602 and an upper pad 603. The lower pad 602 and the upper pad 603 may include, for example, at least one metal material, among aluminum (Al), copper (Cu), nickel (Ni), tungsten (W), platinum (Pt), and gold (Au), but the present disclosure is not limited thereto.

The semiconductor substrate 601 may include semiconductor elements such as silicon and germanium, or compound semiconductors such as silicon carbide (SiC), gallium arsenide (GaAs), indium arsenide (InAs), and indium phosphide (InP).

The upper circuit layer 610 may be disposed on an upper portion of the semiconductor substrate 601, and may include an interlayer insulating layer 611 and an upper connection interconnection 612. The interlayer insulating layer 611 may include silicon oxide or silicon nitride. The upper connection interconnection 612 may connect a first semiconductor chip 300 and a second semiconductor chip 400 to each other or connect the first semiconductor chip 300 and the second semiconductor chip 400 to the through-vias 630.

The lower circuit layer 620 may be disposed on a lower portion of the semiconductor substrate 601, and may include an interlayer insulating layer 621 and a lower connection interconnection 622. The interlayer insulating layer 621 and the lower connection interconnection 622 of the lower circuit layer 620 may respectively include materials similar to those of the interlayer insulating layer 611 and the upper connection interconnection 612 of the upper circuit layer 610 described above.

The through-vias 630 may be through-silicon vias (TSV) passing through the semiconductor substrate 601 in a vertical direction (Z-direction). The through-vias 630 may provide an electrical path connecting the lower pad 602 and the upper pad 603 to each other. The through-via 630 may include a conductive plug and a barrier film surrounding the conductive plug. The conductive plug may include a metal material, for example, tungsten (W), titanium (Ti), aluminum (Al), or copper (Cu). The conductive plug may be formed using a plating process, a PVD process, or a CVD process. The barrier film may include an insulating barrier film and/or a conductive barrier film. The insulating barrier film may be formed of an oxide film, a nitride film, a carbonization film, a polymer, or combinations thereof. The conductive barrier film may include, for example, a metal compound such as tungsten nitride (WN), titanium nitride (TiN), or tantalum nitride (TaN). The barrier film may be formed using a PVD process or a CVD process.

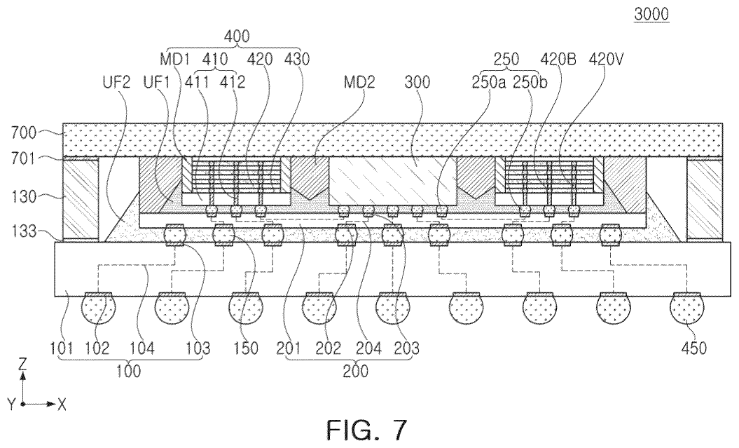

FIG. 7 is a schematic cross-sectional view of a semiconductor package 3000 according to an example embodiment.

Referring to FIG. 7, the semiconductor package 3000, according to an example embodiment, may have features the same as or similar to those described with reference to FIGS. 1 to 6, except that the semiconductor package 3000 further includes a stiffener 130, and a heat sink 700 on the semiconductor chips 300 and 400.

Referring to FIG. 7, the heat sink 700 may control warpage of the semiconductor package 3000 and may externally discharge heat transferred from the first semiconductor chip 300, the second semiconductor chip 400, and the stiffener 130. The heat sink 700 may be formed of a material having excellent thermal conductivity, such as aluminum (Al), gold (Au), silver (Ag), copper (Cu), iron (Fe), graphite, graphene, or the like. The heat sink 700 may have a plate shape, but the present disclosure is not limited thereto. The heat sink 700 may be attached to the stiffener 130 by an insulating thermally conductive layer 701. The insulating thermally conductive layer 701 may include a thermal interface material (TIM), for example, a thermally conductive adhesive tape, thermally conductive grease, or thermally conductive adhesive. In some example embodiments, the insulating thermally conductive layer 701 may also be disposed between the heat sink 700 and the semiconductor chips 300 and 400.

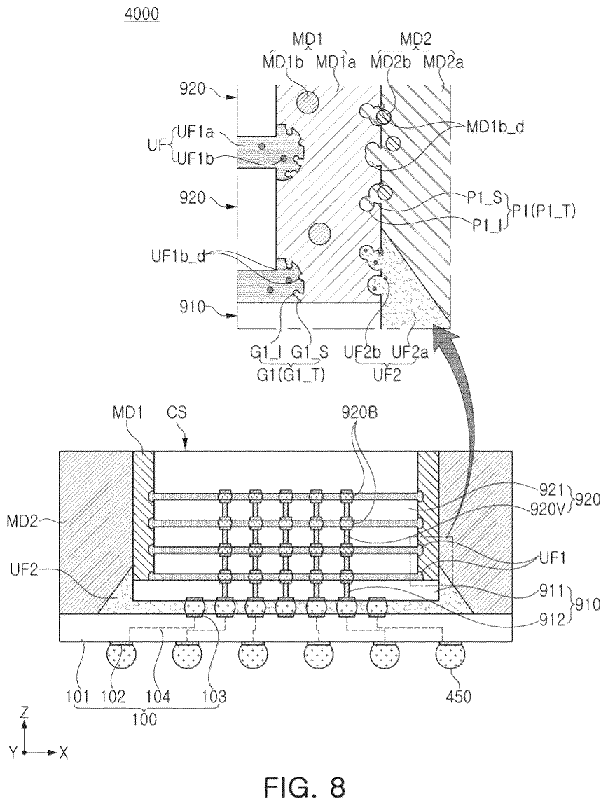

FIG. 8 is a schematic cross-sectional view of a semiconductor package 4000 according to an example embodiment.

Referring to FIG. 8, the semiconductor package 4000, according to an example embodiment, may be the same as or similar to that described with reference to FIGS. 1 to 7, except that a chip structure CS, including one or more semiconductor chips 920 disposed on a base chip 910, is mounted on a substrate 100.

Referring to FIG. 8, the chip structure CS may include the one or more second semiconductor chips 920 disposed on the base chip 910. Each of the second semiconductor chips 920 may include a semiconductor chip 921 and a plurality of through-electrodes 920V penetrating the semiconductor chip 921. The base chip 910 may include a base substrate 911 and a plurality of through-electrodes 912 penetrating the base substrate 911. The one or more second semiconductor chips 920 may be electrically connected to each other through vias 920V passing through at least some second semiconductor chips, among the second semiconductor chips 920. A first underfill layer UF1, surrounding connection bumps 920B, may be disposed between the one or more second semiconductor chips 920. The first underfill layer UF1 may be one of underfill layers including an insulating material such as an epoxy resin. For example, the first underfill layer UF1 may include a non-conductive film (NCF). A plurality of second semiconductor chips 920 may include a memory chip such as DRAM, SRAM, PRAM, ReRAM, FeRAM, MRAM, or flash memory.

The chip structure CS may further include a first encapsulant MD1, encapsulating the one or more second semiconductor chips 920, on the base chip 910. In the present example embodiment, an arrangement relationship of the first underfill layer UF1, the first encapsulant MD1, a second underfill layer UF2, and a second encapsulant MD2 may be the same as or similar to that described with reference to FIGS. 1 to 5B, and thus a detailed description thereof will be omitted.

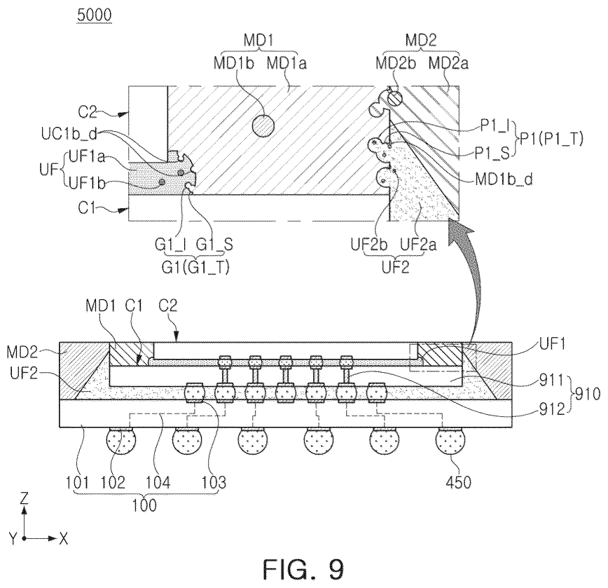

FIG. 9 is a schematic cross-sectional view of a semiconductor package 5000 according to an example embodiment.

Referring to FIG. 9, the semiconductor package 5000, according to an example embodiment, may be the same as or similar to that described with reference to FIGS. 1 to 8, except that different types of chips C1 and C2 are vertically disposed.

Referring to FIG. 9, the different types of chips C1 and C2 may include a logic chip C1 such as a CPU, a GPU, a FPGA, a digital signal processor, an encryption processor, a microprocessor, a microcontroller, an analog-digital converter, or an ASIC, and a memory chip C2 such as a volatile memory such as DRAM or SRAM, and a non-volatile memory such as PRAM, MRAM, RRAM, or flash memory. In the present example embodiment, the memory chip C2 may be vertically disposed on the logic chip C1. In the present example embodiment, an arrangement relationship of a first underfill layer UF1, a first encapsulant MD1, a second underfill layer UF2, and a second encapsulant MD2 may be the same as or similar to that described with reference to FIGS. 1 to 5B, and thus a detailed description thereof will be omitted.

The memory chip C2 may be disposed on the logic chip C1 by copper (Cu)-copper (Cu) bonding. For example, the copper (Cu)-copper (Cu) bonding may be formed between a lower surface of a connection pad of the memory chip C2 and an upper surface of an upper pad of the logic chip C1.

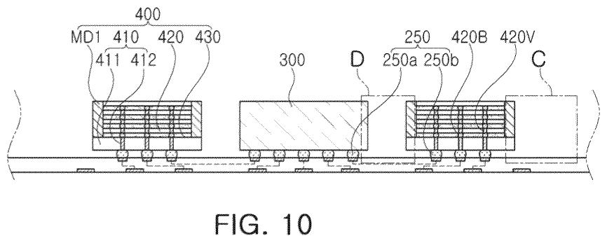

FIGS. 10 to 25 are schematic cross-sectional views and partially enlarged views illustrating a method of manufacturing the semiconductor package 1000A according to one or more example embodiments of the present disclosure.

FIGS. 10, 12, 14, 16, 18, 20, 22, and 24 are schematic cross-sectional views illustrating a method of manufacturing the semiconductor package 1000A according to one or more example embodiments of the present disclosure.

FIGS. 11, 13, 15, 17, 19, 21, 23, and 25 are schematic partially enlarged views of FIGS. 10, 12, 14, 16, 18, 20, 22, and 24 to illustrate a method of manufacturing the semiconductor package 1000A according to one or more example embodiments of the present disclosure. Here, region “D” may be a region corresponding to “A” of FIGS. 2 and 3A, and region “C” may be a region corresponding to “B” of FIGS. 2 and 3B.

Referring to FIG. 10, a first preliminary semiconductor package in which a plurality of semiconductor chips 300 and 400 are disposed on an interposer 200 to be spaced apart from each other in a horizontal direction (X-direction) may be provided to be face-up.

A connection pad of the first semiconductor chip 300 may be attached to an upper pad 203 of the interposer 200 by a first bump structure 250a. A connection pad of the second semiconductor chip 400 may be attached to the upper pad 203 of the interposer 200 by a second bump structure 250b so as to be spaced apart from the first semiconductor chip 300 in the horizontal direction (X-direction).

Referring to FIG. 11, first fillers MD1b of a first encapsulant MD1 of the second semiconductor chip 400 may be formed to be evenly distributed in the first encapsulant MD1. For example, the first surface fillers MD1b_S may be formed to be positioned on a surface of the first encapsulant MD1, and first internal fillers MD1b_I may be formed to be positioned in the first encapsulant MD1. Here, the surface of the first encapsulant MD1 may be smooth due to first surface fillers MD1b_S. At least first internal fillers, among the first internal fillers MD1b_I, may be in contact with the first surface fillers MD1b_S to extend long into the first encapsulant MD1.

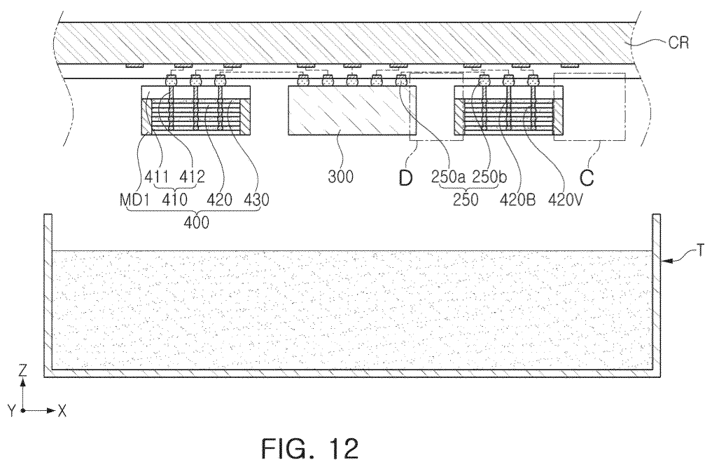

Referring to FIG. 12, a predetermined carrier CR may be attached to a lower portion of the interposer 200 of the first preliminary semiconductor package. Thereafter, the first preliminary semiconductor package to which the carrier CR is attached may be face-down, such that a first etching process may be performed in which the first preliminary semiconductor package is dipped into a water tank T containing an etchant and then taken out.

Referring to FIG. 13, using the first etching process, at least some first fillers, among the first fillers MD1b, may be removed to form first pores P1 on the surface of the first encapsulant MD1. For example, the first surface fillers MD1b_S, positioned on the surface of the first encapsulant MD1, may be removed to form first surface pores P1_S. The first internal fillers MD1b_I in contact with the first surface fillers MD1b_S may also be removed to form first internal pores P1_I connected to the first surface pores P1_S. In this case, the first internal pores P1_I may be connected to the first surface pores P1_S to form first pore tunnels P1_T deeply extending inwardly from the surface of the first encapsulant MD1.

The first fillers MD1b may not be entirely removed (see, e.g., FIG. 3A). Accordingly, fragments MD1b_d of the first fillers may remain in the first pores P1. In addition, at least some fragments, among the fragments MD1b_d of the first fillers, may be present in a direction (Z-direction), perpendicular to the surface of the first encapsulant MD1. This may be understood as the first etching process being performed with the first preliminary semiconductor package to which the carrier CR is attached face-down.

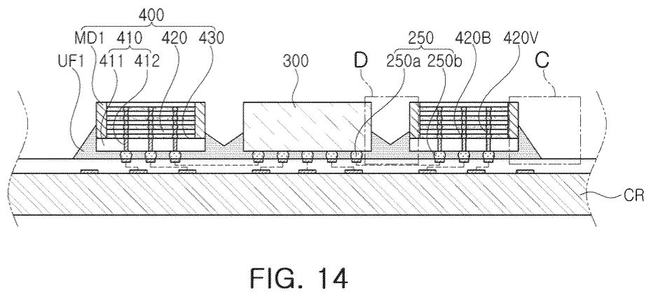

Referring to FIG. 14, after the first etching process is performed, a first underfill layer UF1, surrounding bump structures 250, may be formed between the interposer 200 and the plurality of semiconductor chips 300 and 400.

At least a portion of the first underfill layer UF1 may be formed to be in contact with side surfaces of the plurality of semiconductor chips 300 and 400. For example, the at least a portion of the first underfill layer UF1 may be formed to be in contact with a side surface of the first encapsulant MD1 of the second semiconductor chip 400.

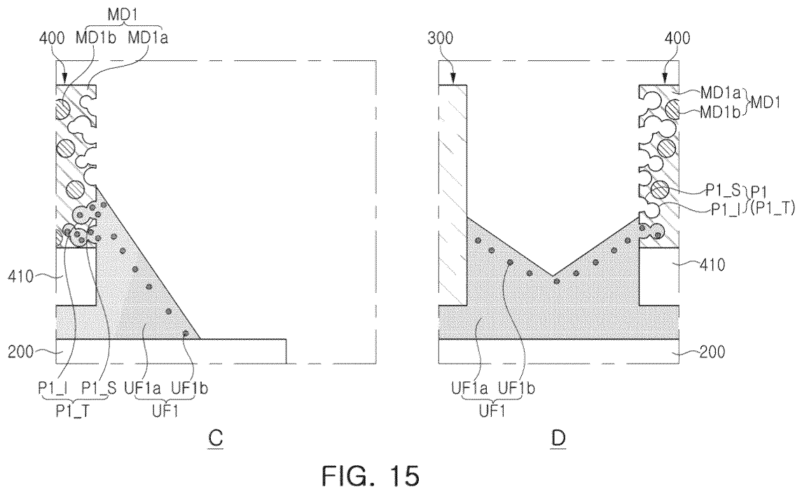

Referring to FIG. 15r, at least a portion of an insulating resin UF1a of the first underfill layer UF1 may fill the first pores P1 (or “first pore tunnel (P1_T)”) positioned in a lower region of the first encapsulant MD1. Here, at least some first binders, among first binders UF1b of the first underfill layer UF1, may be positioned in the first pores P1, and the at least some first binders, among the first binders UF1b, may be in contact with the fragments MD1b_d of the first fillers in or on the surface of the first encapsulant MD1 (see FIG. 3A).

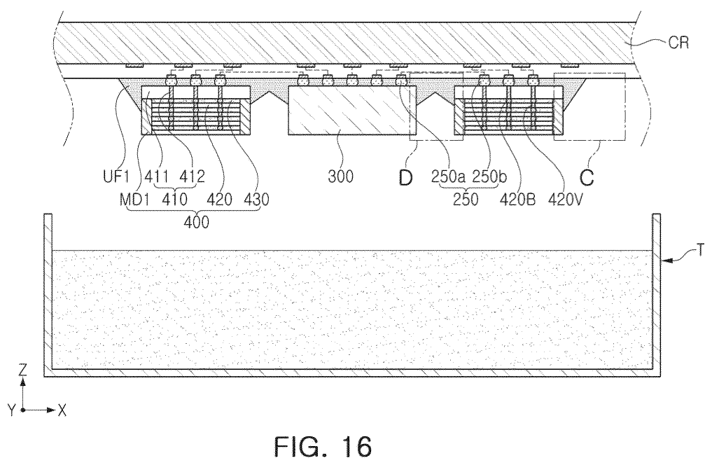

Referring to FIG. 16, after the first underfill layer UF1 in FIG. 12 is formed, the first preliminary semiconductor package may be face-down again, such that a second etching process may be repeatedly performed in which the first preliminary semiconductor package is dipped into a water bath T containing an etchant, and then taken out.

Referring to FIG. 17, in a similar manner to FIG. 13, the at least some first binders, among the first binders UF1b, may be removed by the second etching process to form first pits G1 in a surface of the first underfill layer UF1. For example, first surface binders UF1b_S, positioned on the surface of the first underfill layer UF1, may be removed to form first surface pits G1_S. At least some first internal binders, among first internal binders UF1b_I in contact with the first surface binders UF1b_S, may also be removed to form first internal pits G1_I connected to the first surface pits G1_S. In this case, the first internal pits G1_I may be connected to the first surface pits G1_S to form first pit tunnels G1_T deeply extending inwardly from the surface of the first underfill layer UF1.

Similarly, the first binders UF1b may not be entirely removed (see FIG. 3A). Accordingly, the fragments UF1b_d of the first binders may remain in the first pits G1. In addition, at least some fragments, among the fragments UF1b_d of the first binders, may be present on the surface of the first encapsulant MD1.

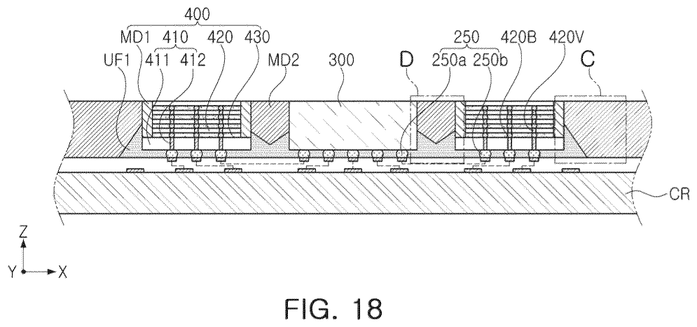

Referring to FIG. 18, after the second etching process, a second encapsulant MD2, surrounding the surface of the first underfill layer UF1 and the side surfaces of the plurality of semiconductor chips 300 and 400, may be formed on the interposer 200.

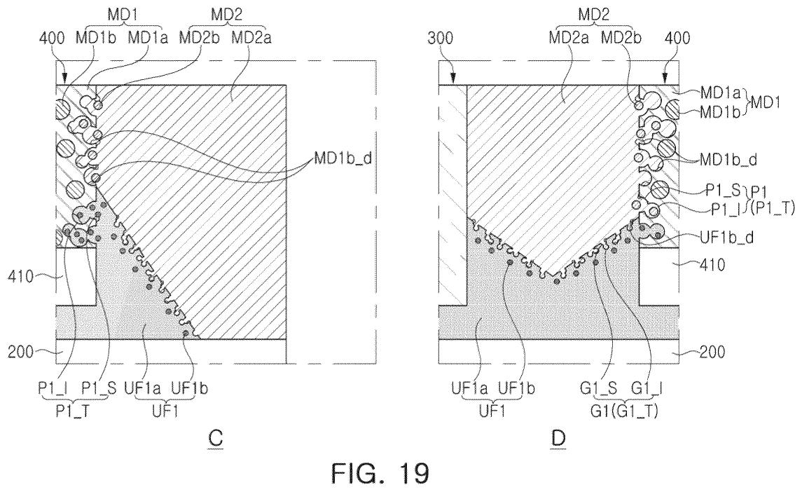

Referring to FIG. 19, at least a portion of a second insulating resin MD2a of the second encapsulant MD2 may fill the first pores P1 (or “first pore tunnel (P1_T)”) positioned in an upper region of the first encapsulant MD1. Here, at least some second fillers, among second fillers MD2b of the second encapsulant MD2, may also be positioned in the first pores P1, and the at least some second fillers, among the second fillers MD2b, may be in contact with the fragments MD1b_d of the first fillers in or on the surface of the first encapsulant MD1 (see FIG. 3A).

The at least a portion of the second insulating resin MD2a of the second encapsulant MD2 may fill the first pits G1 (or “first pit tunnel G1_T”). Here, the at least a portion of the second insulating resin MD2a of the second encapsulant MD2 may be in contact with the fragments UF1b_d of the first binders in the first pits G1 or on the surface of the first underfill layer UF1 (see FIG. 3A).

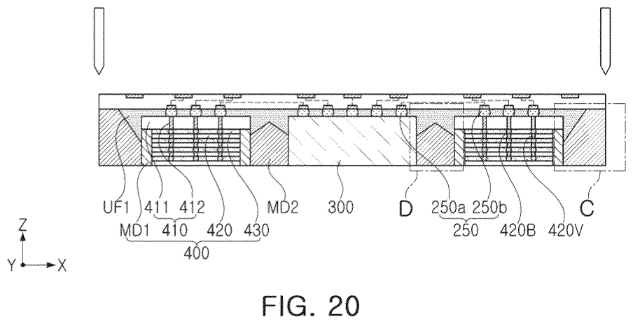

Referring to FIG. 20, after the second encapsulant MD2 in FIG. 18 is formed, a carrier CR may be detached from the interposer 200 and face-down again, such that a sawing process may be performed. A plurality of second preliminary semiconductor packages in which the plurality of semiconductor chips 300 and 400 are molded on the interposer 200 may be formed using the sawing process.

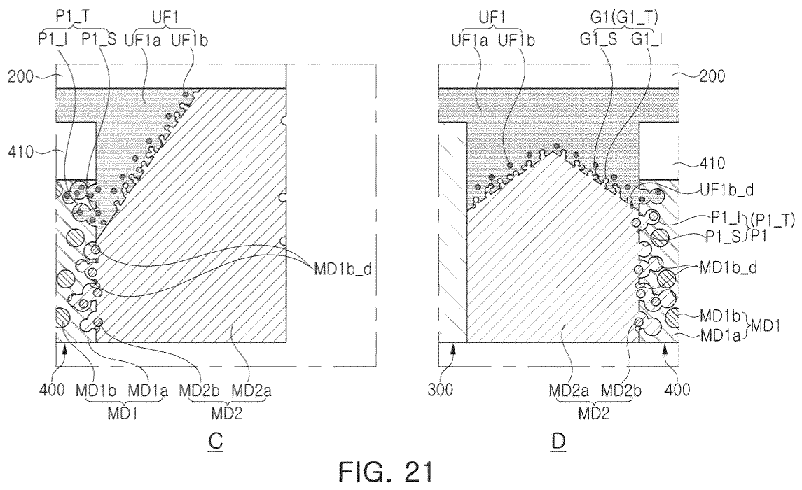

Referring to FIG. 21, using the sawing process, at least some second fillers, among the second fillers MD2b positioned on a side surface of the second encapsulant MD2, may be separated from the side surface of the second encapsulant MD2.

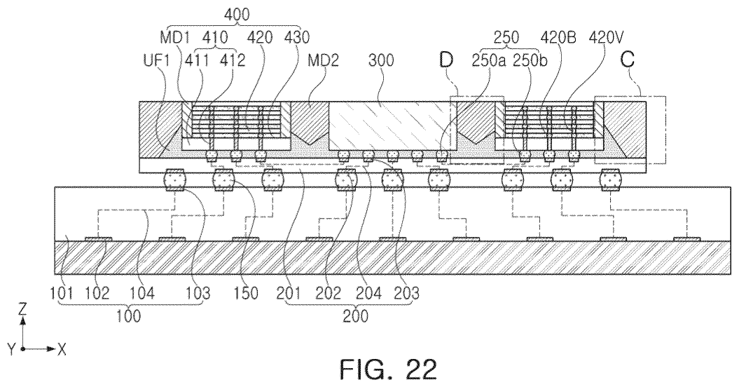

Referring to FIG. 22, the second preliminary semiconductor package may be attached by connection bumps 150 to be face-up on the package substrate 100, thereby providing a third preliminary semiconductor package.

Thereafter, in a similar manner to FIG. 12, a predetermined carrier CR may be re-attached to a lower portion of a package substrate 100 of the third preliminary semiconductor package. Subsequently, the third preliminary semiconductor package to which the carrier CR is attached may be face-down, such that a third etching process may be performed in which the third preliminary semiconductor package is dipped into a water tank T containing an etchant, and then taken out.

Referring to FIG. 23, using the third etching process, at least some second fillers, among the second fillers MD2b, may be removed to form second pores P2 in the side surface of the second encapsulant MD2. Referring to FIGS. 18 and 20 together, before the sawing process is performed, a predetermined etch-stop layer may be additionally formed on an upper surface of the second encapsulant MD2 and upper surfaces of the plurality of semiconductor chips 300 and 400. In this case, even when the third etching process in FIG. 22 is performed, the second pores P2 may not be formed in the upper surface of the second encapsulant MD2.

A description of the second surface pores P2_S, the second internal pores P2_I, and the second pore tunnel P2_T in FIG. 23 may be same as or similar to that of the second surface pores P2_S, the first internal pores P1_I, and the first pore tunnel P1_T described with reference to FIG. 13, and thus a detailed description thereof will be omitted.

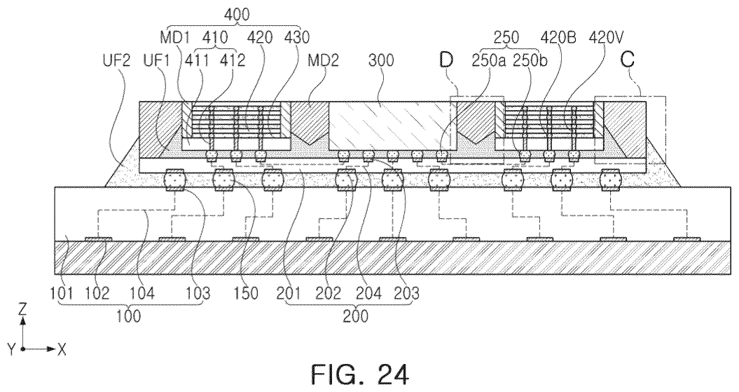

Referring to FIG. 24, after the third etching process is performed, a second underfill layer UF2, surrounding the connection bumps 150 between the package substrate 100 and the interposer 200, may be formed.

At least a portion of the second underfill layer UF2 may be formed to be in contact with a side surface of the second preliminary semiconductor package. For example, the at least a portion of the second underfill layer UF2 may be formed to be in contact with the side surface of the second encapsulant MD2 of the second preliminary semiconductor package.

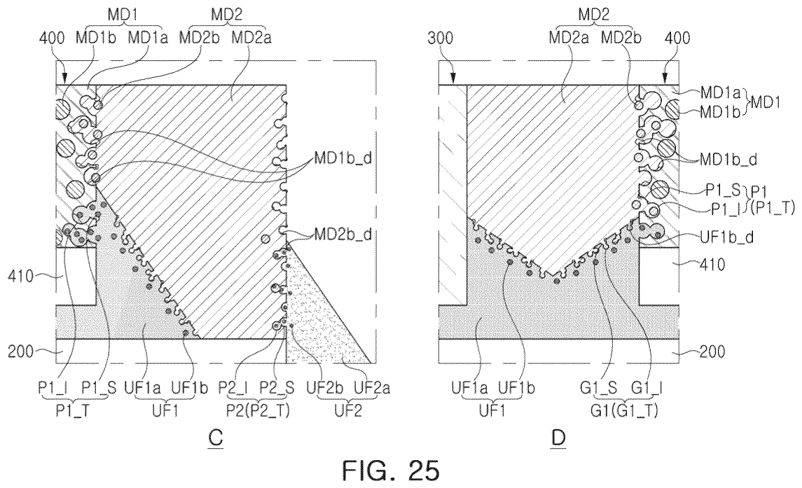

Referring to FIG. 25, at least a portion of an insulating resin UF2a of the second underfill layer UF2 may fill the second pores P2 (or “second pore tunnel (P2_T)”) positioned in a lower region of the second encapsulant MD2. Here, at least some second binders, among the second binders UF2b of the second underfill layer UF2, may be positioned in the second pores P2, and the at least some second binders, among the second binders UF2b, may be in contact with fragments MD1b_d of the second fillers in the second pores P2 or on a surface of the second encapsulant MD2 (see FIG. 3A).

The second pores P2, positioned in an upper region of the second encapsulant MD2, may not be filled with any material. Accordingly, the second pores P2, positioned in the upper region of the second encapsulant MD2, may oppose a side surface of a stiffener 130 in a horizontal direction (X-direction) (see, e.g., FIG. 2).

According to example embodiments of the present disclosure, a semiconductor package may have improved reliability.

While example embodiments have been shown and described above, it will be apparent to those skilled in the art that modifications and variations could be made without departing from the scope of the present disclosure as defined by the appended claims.

What is claimed is:

1. A semiconductor package comprising:
a package substrate comprising a first interconnection;
an interposer on the package substrate, wherein the interposer comprises a second interconnection connected to the first interconnection;
a first chip structure and a second chip structure on the interposer, wherein the first chip structure and the second chip structure are connected to each other through the second interconnection, and wherein the second chip structure comprises:
a base chip;
a chip stack on the base chip; and
a first encapsulant surrounding a side surface of the chip stack, the first encapsulant comprising first pores in a surface thereof;
a first underfill layer between the interposer and the first chip structure, between the interposer and the second chip structure, and in contact with at least a portion of a side surface of each of the first and second chip structures, wherein the first underfill layer comprises a pit in a surface thereof;
a second encapsulant covering at least a portion of the side surface of each of the first chip structure and the second chip structure and covering the surface of the first underfill layer, wherein the second encapsulant comprises a second pore in a surface thereof; and
a second underfill layer between the package substrate and the interposer, the second underfill layer in contact with at least a portion of a side surface of the second encapsulant,
wherein at least a portion of the first underfill layer fills one or more of the first pores,
wherein at least a portion of the second encapsulant fills one or more of the first pores and the pit, and
wherein at least a portion of the second underfill layer fills the second pore.

2. The semiconductor package of claim 1,
wherein at least one of the first pores among the one or more of the first pores filled by at least a portion of the first underfill layer is positioned in a lower region of the first encapsulant,
wherein at least one of the first pores among the one or more of the first pores filled by at least a portion of the second encapsulant is positioned in an upper region of the first encapsulant, and
wherein the second pore is positioned in a lower region of the second encapsulant.

3. The semiconductor package of claim 2, wherein a volume of the at least a portion of the first underfill layer is less than a volume of the at least a portion of the second encapsulant.

4. The semiconductor package of claim 1,
wherein the second encapsulant further comprises a second pore in a surface thereof, and
wherein the second pore is positioned in an upper region of the second encapsulant and is not filled with any material.

5. The semiconductor package of claim 1,
wherein the first encapsulant comprises a first filler, and
wherein the second encapsulant comprises a second filler having a volume substantially the same as a volume of the first filler.

6. The semiconductor package of claim 1,
wherein the first encapsulant comprises a first filler, and
wherein the second encapsulant comprises a second filler having a volume less than a volume of the first filler.

7. The semiconductor package of claim 6, wherein the second filler is positioned in a first pore among the first pores.

8. The semiconductor package of claim 1,
wherein the first encapsulant comprises a first filler, and
wherein the first underfill layer comprises a binder having a volume less than a volume of the first filler.

9. The semiconductor package of claim 8, wherein the binder is positioned in a first pore among the first pores.

10. The semiconductor package of claim 1,
wherein the second encapsulant comprises a filler, and
wherein the filler is not disposed in the pit.

11. The semiconductor package of claim 1,
wherein the second encapsulant comprises fillers,
wherein the first underfill layer comprises binders,
wherein one or more of the first pores are positioned in an upper region of the first encapsulant and are filled by the fillers,
wherein one or more of the first pores are positioned in a lower region of the first encapsulant and are filled by the binders, and
wherein a number of binders is greater than a number of fillers.

12. The semiconductor package of claim 1,
wherein the first encapsulant comprises a first filler, the second encapsulant comprises a second filler, the first underfill layer comprises a first binder, and the second underfill layer comprises a second binder, and
wherein the first filler, the second filler, the first binder, and the second binder have a spherical shape.

13. The semiconductor package of claim 1, wherein the first encapsulant and the second encapsulant comprise different insulating resins.

14. The semiconductor package of claim 1, wherein the first encapsulant and the second encapsulant include an insulating resin.

15. A semiconductor package comprising:
a base chip;
a semiconductor chip on the base chip;
a bump structure disposed between the base chip and the semiconductor chip;
an underfill layer surrounding the bump structure, the underfill layer comprising first pits in a surface thereof; and
a first encapsulant in contact with a side surface of the semiconductor chip and the surface of the underfill layer,
wherein at least some first pits, among the first pits, are connected to each other to form a first pit tunnel leading inwardly from the surface of the underfill layer, and
wherein at least a portion of the first encapsulant fills the first pit tunnel.

16. The semiconductor package of claim 15,
wherein a side surface of the first encapsulant comprises first pores,
wherein the semiconductor package further comprises:
a base substrate below the base chip;
a connection bump between the base chip and the base substrate, the connection bump connecting the base chip and the base substrate to each other; and
a second underfill layer surrounding the connection bump, the second underfill layer in contact with at least a portion of the side surface of the first encapsulant and having second pits in a surface thereof,
wherein at least some first pores, among the first pores, are connected to each other to form a first pore tunnel in a lower region of the side surface of the first encapsulant, the first pore tunnel leading inwardly from the side surface of the first encapsulant, and
wherein at least a portion of the second underfill layer fills the first pore tunnel.

17. The semiconductor package of claim 16, further comprising:
a second encapsulant in contact with the side surface of the first encapsulant and a side surface of the second underfill layer,
wherein at least some second pits, among the second pits, are connected to each other to form a second pit tunnel leading inwardly from the surface of the second underfill layer,
wherein at least some first pores, among the first pores, are connected to each other to form a second first pore tunnel in an upper region of the side surface of the first encapsulant, the second first pore tunnel leading inwardly from the side surface of the first encapsulant, and
wherein at least a portion of the second encapsulant fills the second pit tunnel and the second first pore tunnel.

18. The semiconductor package of claim 17,
wherein the first encapsulant comprises a first insulating resin and a first filler, and
wherein the second encapsulant comprises a second insulating resin different from the first insulating resin, and a second filler having a volume less than a volume of the first filler.

19. The semiconductor package of claim 17,
wherein the first encapsulant comprises a first insulating resin and first fillers, the second encapsulant comprises a second insulating resin, the underfill layer comprises first binders, and the second underfill layer comprises a third insulating resin and second binders,
wherein the first insulating resin is in contact with a fragment of a first binder among the first binders in a first pit among the first pits,
wherein the second insulating resin is in contact with a fragment of a first filler, among the first fillers, in a first pore among the first pores,
wherein the third insulating resin is in contact with a fragment of a first filler, among the first fillers, in a first pore among the first pores, and
wherein the second insulating resin is in contact with a fragment of a second binder among the second binder in a second pit among the second pits.

20. A semiconductor package comprising:
a base substrate;
a first semiconductor chip on the base substrate;
a connection bump between the base substrate and the first semiconductor chip;
a second semiconductor chip on the first semiconductor chip;
a first encapsulant in contact with a side surface of the second semiconductor chip, wherein the first encapsulant comprises first pores in a surface thereof;
a first underfill layer surrounding the connection bump, wherein the first underfill layer is in contact with a side surface of a lower region of the first encapsulant, and wherein the first underfill layer comprises a first pit in a surface thereof; and
a second encapsulant, wherein the second encapsulant is in contact with a side surface of an upper region of the first encapsulant,
wherein the first underfill layer fills a first pore, among the first pores, positioned in the lower region of the first encapsulant, and
wherein the second encapsulant fills the first pit and a first pore, among the first pores, positioned in the upper region of the first encapsulant.
